(19) United States
(12) Patent Application Publication
(10) Pub. No.: US 2015/0171351 A1
(43) Pub. Date: Jun. 18, 2015

(54) LIGHT-EMITTING COMPOUND

(71) Applicants: Cambridge Display Technology Limited, Godmanchester (GB); Sumitomo Chemical Company Limited, Tokyo (JP)

(72) Inventors: Annette Steudel, Dresden (DE); Valery Kozhevnikov, Godmanchester (GB)

(21) Appl. No.: 14/413,821

(22) PCT Filed: Jul. 9, 2013
(86) PCT No.: PCT/GB2013/051815

§ 371 Date: Jan. 9, 2015

(30) Foreign Application Priority Data
Jul. 10, 2012 (GB) 1212242.0
Jul. 10, 2012 (GB) 1212243.8

(51) Int. Cl. H01L 51/00; C07F 15/00

(52) U.S. Cl. CPC H01L 51/0087; C07F 15/0086; H01L 51/5221

(57) ABSTRACT

A compound of formula (I): wherein R¹ in each occurrence is independently H or a substituent; R² in each occurrence is independently a substituent; p in each occurrence is 0, 1, 2, 3 or 4 and Y is a ligand, with the proviso that at least one R¹ is a substituent or at least one p is at least 1.

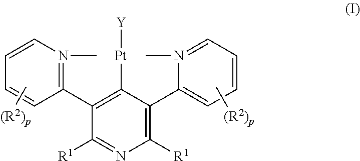

### FIELD OF THE INVENTION

The present invention relates to light-emitting compounds, in particular phosphorescent light-emitting compounds; compositions, formulations and light-emitting devices comprising said light-emitting compounds; and methods of making said light-emitting devices.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

Suitable light-emitting materials include small molecule, polymeric and dendrimeric materials. Suitable light-emitting polymers include poly(arylene vinylenes) such as poly(p-phenylene vinylenes) and polyarylenes such as polyfluorenes.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of singlet excitons).

Phosphorescent dopants are also known (that is, a light-emitting dopant in which light is emitted via decay of triplet excitons). Known phosphorescent dopants include complexes of heavy transition metals.

Lee et al, Inorganic Chemistry 48(3), 2009, 1030-1037 discloses the following blue light-emitting compound:

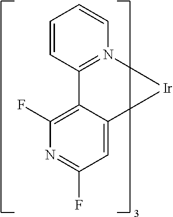

US 2006/0098475 discloses platinum complexes for light-emitting devices.

Yang et al, Appl. Phys. Lett. 93, 193305, 2008 discloses a white phosphorescent OLED containing the blue-emitting complex platinum (II) [,3-difluoro-di(2-pyridinyl)benzene]chloride.

Kalinowski et al, Adv. Mater. 2007, 19, 4000-40005 discloses a white phosphorescent OLED containing the following blue light-emitting material:

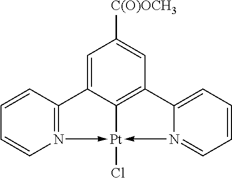

It is an object of the invention to provide blue phosphorescent light-emitting compounds, including deep blue phosphorescent light-emitting compounds.

Murphy et al, “Blue-shifting the monomer and excimer phosphorescence of tridentate cyclometallated platinum (II) complexes for optimal white-light OLEDs” Chem. Commun. 2012 DOI: 10.1039/c2cc31330 h discloses the following compound:

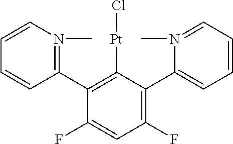

Wang et al, “Facile Synthesis and Characterisation of Phosphorescent Pt(N—C—N)X Complexes”, Inorg. Chem., 2010, 49(24), 11276-11286 discloses the following compound:

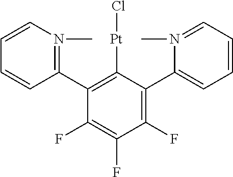

### SUMMARY OF THE INVENTION

In a first aspect the invention provides a compound of formula (I):

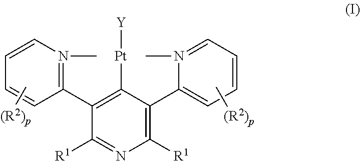

wherein R¹ in each occurrence is independently H or a substituent; R² in each occurrence is independently a substituent; p in each occurrence is 0, 1, 2, 3 or 4 and Y is a ligand, with the proviso that at least one R¹ is a substituent or at least one p is at least 1.

Optionally, both groups R¹ are a substituent and each p is independently 0, 1, 2, 3 or 4.

Optionally, at least one R¹ group, optionally each R¹ group, is an electron-withdrawing group, optionally fluorine.

In one optional arrangement, each p is 0.

In another optional arrangement, at least one p, optionally each p, is at least 1.

Optionally, each p is 1.

Optionally, the at least one R² group is an electron donating substituent Optionally, R² is selected from the group consisting of: hydrocarbyl, optionally a C₁₋₃₀ hydrocarbyl; *—OR¹²; *—NR¹²; and *—BR¹²₂, wherein * represents a point of attachment to the metal complex and R¹² independently in each occurrence is a hydrocarbyl, optionally C₁₋₃₀ hydrocarbyl, optionally C₁₋₂₀ alkyl or phenyl substituted with one or more C₁₋₂₀ alkyl groups and wherein two R¹² groups linked to the same N or B atom may be linked to form a ring.

Optionally, the at least one R² comprises a tertiary carbon atom.

Optionally, the at least one R² is a C₁₋₂₀ alkyl.

Optionally, the at least one R² is an optionally substituted phenyl.

Optionally, Y is selected from halogen, unsubstituted or substituted phenoxy, cyano and a group of formula:

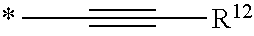

wherein R¹² is a hydrocarbyl, optionally C₁₋₃₀ hydrocarbyl, optionally C₁₋₂₀ alkyl or phenyl substituted with one or more C₁₋₂₀ alkyl groups.

Optionally, a photoluminescence spectrum of the compound has a peak at a wavelength of less than 480 nm, optionally less than 470 nm.

In a second aspect the invention provides a composition comprising a charge-transporting host material and a compound according to the first aspect.

Optionally according to the second aspect, the compound of formula (I) is provided in an amount of at least 5 weight % of the composition, optionally less than 10 weight % of the composition.

In a third aspect the invention provides a white light-emitting composition comprising a compound according to the first aspect.

In one optional arrangement according to the third aspect, the composition comprises one or more light emitting materials in addition to the compound of the first aspect.

In another optional arrangement according to the third aspect, the compound of the first aspect is the only light emitting material in the composition.

In a fourth aspect the invention provides a formulation comprising a compound according to the first aspect or a composition according to the second or third aspects and at least one solvent.

In a fifth aspect the invention provides an organic light-emitting device comprising an anode, a cathode and a light-emitting layer between the anode and the cathode wherein the light-emitting layer comprises a compound according to the first aspect.

Optionally according to the fifth aspect the light-emitting layer comprises a composition according to the second or third aspects.

In a sixth aspect the invention provides a method of forming an organic light-emitting device according to the fifth aspect, the method comprising the step of forming the light-emitting layer over one of the anode and cathode, and forming the other of the anode and cathode over the light-emitting layer.

Optionally according to the sixth aspect the light-emitting layer is formed by depositing a formulation according to the fourth aspect and evaporating the at least one solvent.

### DESCRIPTION OF THE DRAWINGS

The invention will now be described in more detail with reference to the Figures, in which:

FIG. 1 illustrates an OLED according to an embodiment of the invention; and

FIG. 2 is a photoluminescence spectrum of a composition according to an embodiment of the invention and a comparative composition.

### DETAILED DESCRIPTION OF THE INVENTION

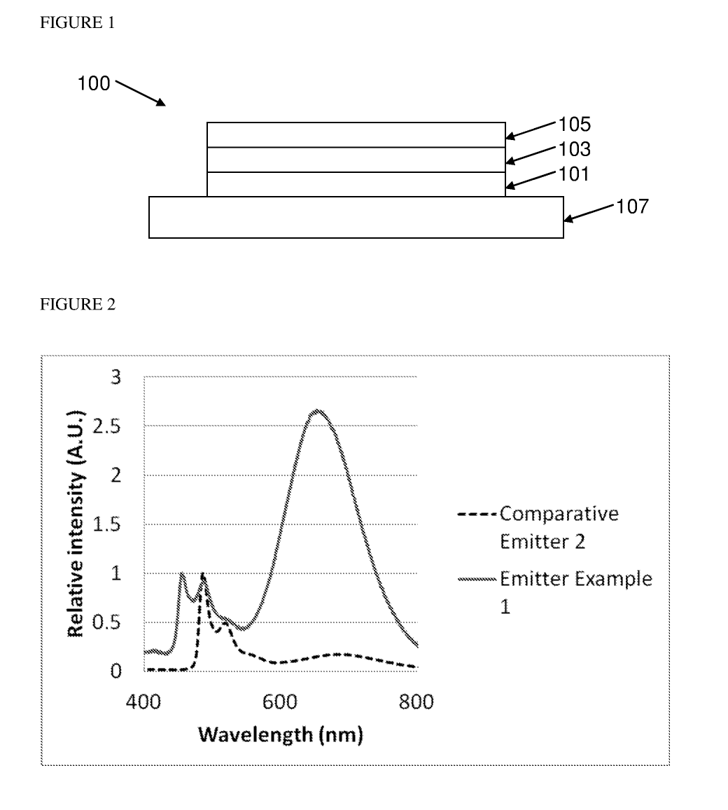

FIG. 1, which is not drawn to any scale, illustrates schematically an OLED according to an embodiment of the invention. The OLED is carried on substrate 1 and comprises an anode 2, a cathode 4 and a light-emitting layer 3 between the anode and the cathode. Further layers (not shown) may be provided between the anode and the cathode including, without limitation, charge-transporting layers, charge-blocking layers and charge injection layers. The device may contain more than one light-emitting layer.

Exemplary OLED structures including one or more further layers include the following:

Anode/Hole-injection layer/Light-emitting layer/Cathode
Anode/Hole transporting layer/Light-emitting layer/Cathode
Anode/Hole-injection layer/Hole-transporting layer/Light-emitting layer/Cathode
Anode/Hole-injection layer/Hole-transporting layer/Light-emitting layer/Electron-transporting layer/Cathode.

In one preferred embodiment, the OLED comprises at least one, optionally both, of a hole injection layer and a hole transporting layer.

Light-emitting layer 3 may contain a host material and a phosphorescent compound of formula (I). Light-emitting layer may contain further light-emitting compounds, for example further phosphorescent or fluorescent light-emitting materials having a colour of emission differing from that of the compound of formula (I). The host material may combine holes injected from the anode and electrons injected from the cathode to form singlet and triplet excitons. The triplet excitons at least may be transferred to the phosphorescent compound, and decay from a triplet excited state of the phosphorescent compound to produce phosphorescence.

### Phosphorescent Compound

With reference to compounds of formula (I) described above, the tridentate ligand of these compounds contains three pyridine rings. The two outer rings are co-ordinated to the central metal ion through N atoms, and the central ring of the tridentate ligand is co-ordinated through a C atom.

One or more substituents R² on one or both of the outer rings of the complex may be provided.

Substitutents R¹ and R² may be selected according to their effect on colour of emission of the metal complex.

One or two electron-withdrawing substituents R¹ may cause emission of the metal complex to shift to a shorter wavelength as compared to a complex in which substituents R¹ are not present. Conversely, one or two electron-donating substituents R¹ may cause emission of the metal complex to shift to a longer wavelength as compared to a complex in which substituents R¹ are not present.

One or more electron-donating substituents R² may cause emission of the metal complex to shift to a shorter wavelength as compared to a complex in which substituents R² are not present. Conversely, one or more electron-withdrawing substituents R² may cause emission of the metal complex to shift to a longer wavelength as compared to a complex in which substituents R² are not present.

Where present, there is preferably only one group R² per pyridine ring. Preferably, electron-donating substituents R² are substituted at the 4-position of the pyridine ring they are bound to.

Electron withdrawing substituents may be substituents having a positive Hammett constant.

Electron-donating substituents may be substituents having a negative Hammett constant.

Exemplary electron-donating substituents include hydrocarbyl groups, optionally C₁₋₆₀ or C₁₋₃₀ hydrocarbyl, and groups of formula *—OR¹²; *—NR¹² ; or *—BR¹²₂, wherein * represents a point of attachment to the metal complex and R¹² independently in each occurrence is a hydrocarbyl, optionally C₁₋₄₀ hydrocarbyl, optionally C₁₋₂₀ alkyl or phenyl substituted with one or more C₁₋₂₀ alkyl groups and wherein two R¹² groups linked to the same N or B atom may be linked to form a ring.

Exemplary hydrocarbyl substituents R¹ and R² include the following:
C₁₋₂₀ alkyl
Phenyl substituted with one or more C₁₋₂₀ alkyl groups
A branched or linear chain of two or more phenyl rings, each of which ring may be substituted with one or more C₁₋₂₀ alkyl groups.

Exemplary substituents having branched or linear phenyl chains include the following, each of which may be substituted with one or more C₁₋₂₀ alkyl groups:

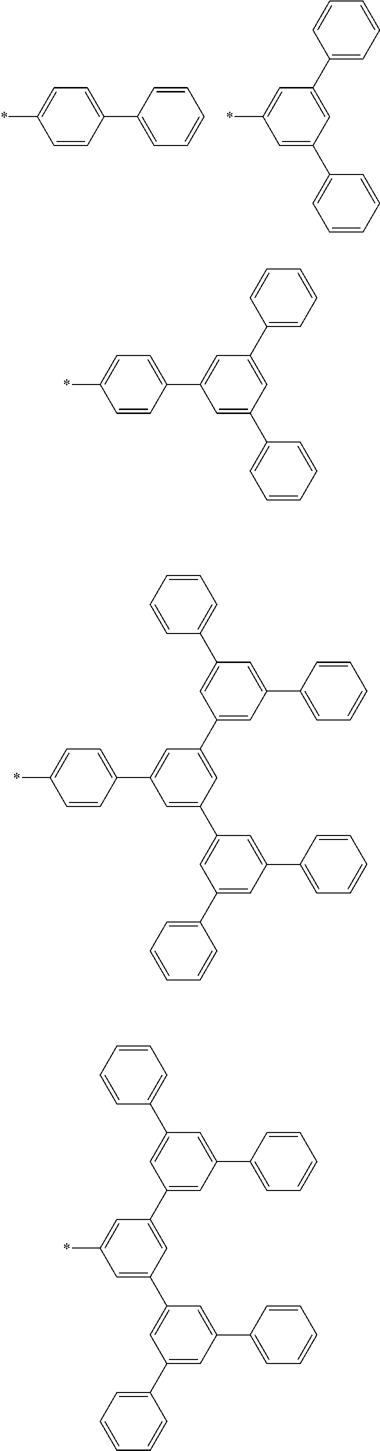

wherein * represents a point of attachment of the substituent to the metal complex.

One or more bulky substituents R² may allow control of formation of excimers, in particular at relatively high concentrations of compounds of the invention. Exemplary bulky substituents include substituents containing a tertiary carbon atom, and substituents containing one or more phenyl groups.

Where present, substituents R² are preferably provided para- to the N atom of the pyridine ring they are bound to.

The two outer pyridine rings of the compound of formula (I) may differ in one or more of: value of p; identity of R²; and substitution position of R². In one embodiment, p of one pyridine ring is 0 and p of the other pyridine ring is at least 1.

Hydrocarbyl substituents may improve solubility of a compound of formula (I) in common organic solvents, for example mono- or poly-alkyl benzenes and anisole, as compared to a compound of formula (I) in which such hydrocarbyl substituents are absent.

Exemplary electron-withdrawing substituents R¹ and R² include fluorine.

Exemplary ligands Y include halogen, phenoxy, cyano and acetylenic groups. Phenoxy ligand Y may be unsubstituted or substituted with one or more substituents, optionally one or more C₁₋₂₀ alkyl groups. A preferred halogen Y is chlorine.

Specific examples of compounds according to the invention include the following:

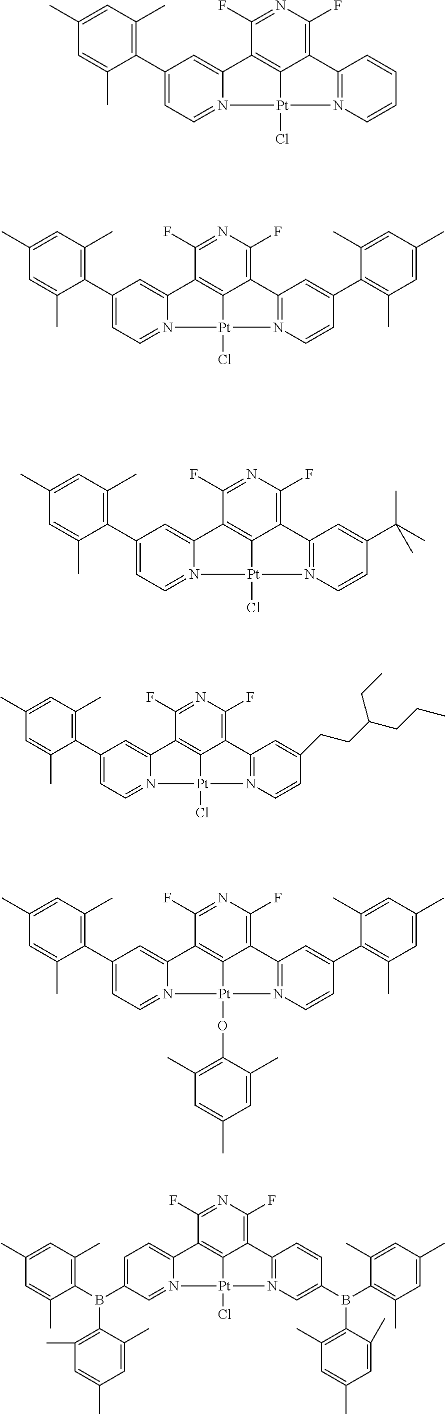

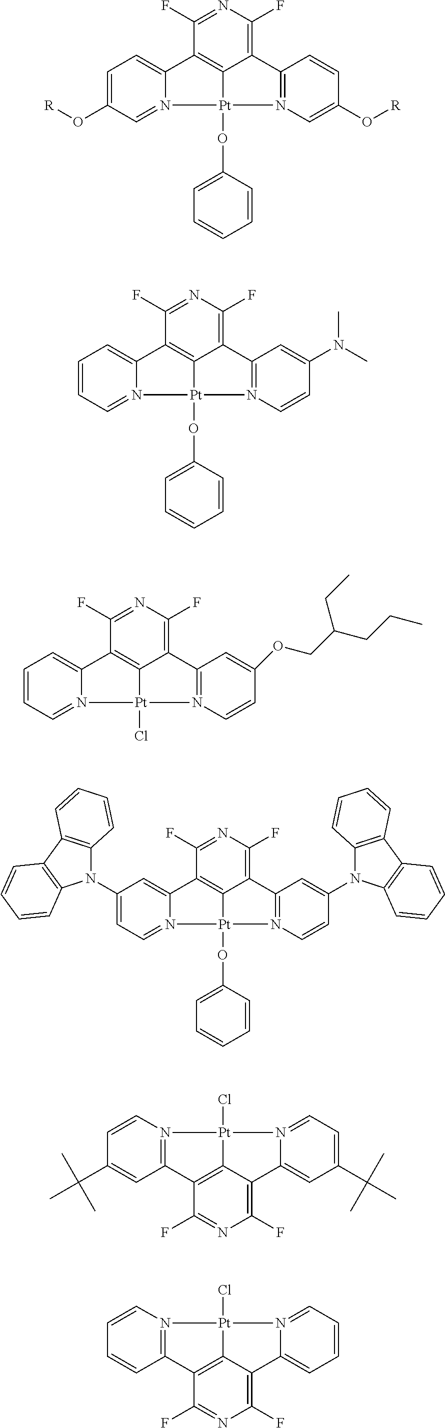

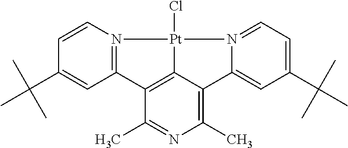

The compound of formula (I) may emit blue light, and may have a photoluminescence spectrum with a peak of less than 480 nm, optionally a peak in the range of 420-470 nm.

### Host Material

The host material has a triplet excited state energy level T₁ that is preferably no more than 0.1 lower than, and preferably at least the same as or higher than, the phosphorescent compound of formula (I) in order to allow transfer of triplet excitons from the host material to the phosphorescent compound of formula (I).

The triplet excited state energy levels of the host material and the phosphorescent compound may be determined from their respective phosphorescence spectra.

The host material may be a polymer or a non-polymeric compound.

The compound of formula (I) may be mixed with the host material or may be bound to the host material. In the case where the host material is a polymer, the metal complex may be provided as a main chain unit, a side group or an end group of the polymer.

In the case where the compound of formula (I) is provided as a side group, the metal complex may be directly bound to a main chain of the polymer or spaced apart from the main chain by a spacer group. Exemplary spacer groups include C₁₋₂₀ alkyl groups, aryl-C₁₋₂₀ alkyl groups and C₁₋₂₀ alkoxy groups. The polymer main chain or spacer group may be bound to the tridentate ligand of the compound of formula (I).

If the compound of formula (I) is bound to a polymer comprising conjugated repeat units then it may be bound to the polymer such that there is no conjugation between the conjugated repeat units and the compound of formula (I), or such that the extent of conjugation between the conjugated repeat units and the compound of formula (I) is limited.

Exemplary host polymers include polymers having a non-conjugated backbone with charge-transporting groups pendant from the non-conjugated backbone, for example poly(9-vinylcarbazole), and polymers comprising conjugated repeat units in the backbone of the polymer. If the backbone of the polymer comprises conjugated repeat units then the extent of conjugation between repeat units in the polymer backbone may be limited in order to maintain a triplet energy level of the polymer that is no lower than that of the phosphorescent compound of formula (I).

Exemplary repeat units of a conjugated polymer include optionally substituted monocyclic and polycyclic arylene repeat units as disclosed in for example, Adv. Mater. 2000 12(23) 1737-1750 and include: 1,2-, 1,3- and 1,4-phenylene repeat units as disclosed in J. Appl. Phys. 1996, 79, 934; 2,7-fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

One exemplary class of arylene repeat units is optionally substituted fluorene repeat units, such as repeat units of formula IV:

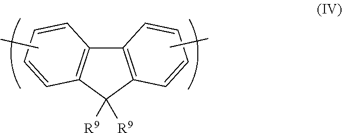

wherein R⁹ in each occurrence is the same or different and is H or a substituent, and wherein the two groups R⁹ may be linked to form a ring.

Each R⁹ is preferably a substituent, and each R⁹ may independently be selected from the group consisting of:
optionally substituted alkyl, optionally C₁₋₂₀ alkyl, wherein one or more non-adjacent C atoms may be replaced with optionally substituted aryl or heteroaryl, O, S, substituted N, C═O or —COO—;
optionally substituted aryl or heteroaryl;
a linear or branched chain of aryl or heteroaryl, each of which groups may independently be substituted, for example a group of formula —(Ar⁶)ᵣ as described below with reference to formula (VII); and
a crosslinkable-group, for example a group comprising a double bond such and a vinyl or acrylate group, or a benzocyclobutane group.

In the case where R⁹ comprises aryl or heteroaryl ring system, or a linear or branched chain of aryl or heteroaryl ring systems, the or each aryl or heteroaryl ring system may be substituted with one or more substituents R³ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵, and
fluorine, nitro and cyano;
   wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

Optional substituents for one or more of the aromatic carbon atoms of the fluorene unit are preferably selected from the group consisting of alkyl, for example C₁₋₂₀ alkyl, wherein one or more non-adjacent C atoms may be replaced with O, S, NH or substituted N, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

Where present, substituted N may independently in each occurrence be NR⁶ wherein R⁶ is alkyl, optionally C₁₋₂₀ alkyl, or optionally substituted aryl or heteroaryl. Optional substituents for aryl or heteroaryl R⁶ may be selected from R⁴ or R⁵.

Preferably, each R⁹ is selected from the group consisting of C₁₋₂₀ alkyl and optionally substituted phenyl. Optional substituents for phenyl include one or more C₁₋₂₀ alkyl groups.

If the compound of formula (I) is provided as a side-chain of the polymer then at least one R⁹ may comprise a compound of formula (I) that is either bound directly to the 9-position of a fluorene unit of formula (IV) or spaced apart from the 9-position by a spacer group.

The repeat unit of formula (IV) may be a 2,7-linked repeat unit of formula (IVa):

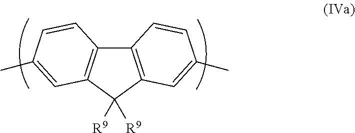

Optionally, the repeat unit of formula (IVa) is not substituted in a position adjacent to the 2- or 7-positions.

The extent of conjugation of repeat units of formulae (IV) may be limited by (a) linking the repeat unit through the 3- and/or 6-positions to limit the extent of conjugation across the repeat unit, and/or (b) substituting the repeat unit with one or more further substituents R¹ in or more positions adjacent to the linking positions in order to create a twist with the adjacent repeat unit or units, for example a 2,7-linked fluorene carrying a C₁₋₂₀ alkyl substituent in one or both of the 3- and 6-positions.

Another exemplary class of arylene repeat units is phenylene repeat units, such as phenylene repeat units of formula (V):

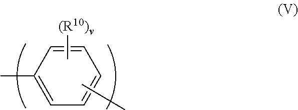

wherein v is 0, 1, 2, 3 or 4, optionally 1 or 2, and R¹⁰ independently in each occurrence is a substituent, optionally a substituent R⁹ as described above with reference to formula (IV), for example C₁₋₂₀ alkyl, and phenyl that is unsubstituted or substituted with one or more C₁₋₂₀ alkyl groups.

The repeat unit of formula (V) may be 1,4-linked, 1,2-linked or 1,3-linked.

If the repeat unit of formula (V) is 1,4-linked and if v is 0 then the extent of conjugation of repeat unit of formula (V) to one or both adjacent repeat units may be relatively high.

If v is at least 1, and/or the repeat unit is 1,2- or 1,3 linked, then the extent of conjugation of repeat unit of formula (V) to one or both adjacent repeat units may be relatively low. In one preferred arrangement, the repeat unit of formula (V) is 1,3-linked and v is 0, 1, 2 or 3. In another preferred arrangement, the repeat unit of formula (V) has formula (Va):

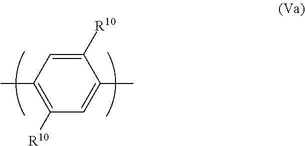

A host polymer may comprise charge-transporting units CT that may be hole-transporting units or electron transporting units.

A hole transporting unit may have a low electron affinity (2 eV or lower) and low ionisation potential (5.8 eV or lower, preferably 5.7 eV or lower, more preferred 5.6 eV or lower).

An electron-transporting unit may have a high electron affinity (1.8 eV or higher, preferably 2 eV or higher, even more preferred 2.2 eV or higher) and high ionisation potential (5.8 eV or higher) Suitable electron transport groups include groups disclosed in, for example, Shirota and Kageyama, Chem. Rev. 2007, 107, 953-1010.

Electron affinities and ionisation potentials may be measured by cyclic voltammetry (CV) wherein the working electrode potential is ramped linearly versus time.

When cyclic voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinium counter electrode (donor or acceptor of electrons) and a reference glass electrode no leak Ag/AgCl. Ferrocene is added in the cell at the end of the experiment for calculation purposes. (Measurement of the difference of potential between Ag/AgCl/ferrocene and sample/ferrocene).

### Method and Settings:

3 mm diameter glassy carbon working electrode
Ag/AgCl/no leak reference electrode
Pt wire auxiliary electrode
0.1 M tetrabutylammonium hexafluorophosphate in acetonitrile
LUMO=4.8-ferrocene (peak to peak maximum average)+onset
Sample: 1 drop of 5 mg/mL in toluene spun at 3000 rpm LUMO (reduction) measurement: A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline.

Exemplary hole-transporting units CT include optionally substituted (hetero)arylamine repeat units, for example repeat units of formula (VI):

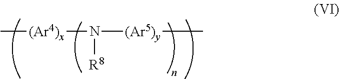

wherein Ar⁴ and Ar⁵ in each occurrence are independently selected from optionally substituted aryl or heteroaryl, n is greater than or equal to 1, preferably 1 or 2, R⁸ is H or a substituent, preferably a substituent, and x and y are each independently 1, 2 or 3.

Ar⁴ and Ar⁵ may each independently be a monocyclic or fused ring system.

R⁸, which may be the same or different in each occurrence when n>1, is preferably selected from the group consisting of alkyl, for example C₁₋₂₀ alkyl, Ar⁶, a branched or linear chain of Ar⁶ groups, or a crosslinkable unit that is bound directly to the N atom of formula (VI) or spaced apart therefrom by a spacer group, wherein Ar⁶ in each occurrence is independently optionally substituted aryl or heteroaryl. Exemplary spacer groups are as described above, for example C₁₋₂₀ alkyl, phenyl and phenyl-C₁₋₂₀ alkyl.

Ar⁶ groups may be substituted with one or more substituents as described below. An exemplary branched or linear chain of Ar⁶ groups may have formula —(Ar⁶)r, wherein Ar⁶ in each occurrence is independently selected from aryl or heteroaryl and r is at least 1, optionally 1, 2 or 3. An exemplary branched chain of Ar⁶ groups is 3,5-diphenylbenzene.

Any of Ar⁴, Ar⁵ and Ar⁶ may independently be substituted with one or more substituents. Preferred substituents are selected from the group R¹¹ consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵,
fluorine, nitro and cyano;
   wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

Any two of Ar⁴, Ar⁵ and, if present, Ar⁶ in the repeat unit of Formula (VI) that are directly linked to a common N atom may be linked by a direct bond or a divalent linking atom or group. Preferred divalent linking atoms and groups include O, S; substituted N; and substituted C.

Where present, substituted N or substituted C of R¹¹, R⁴ or of the divalent linking group may independently in each occurrence be NR⁶ or CR⁶₂ respectively wherein R⁶ is alkyl or optionally substituted aryl or heteroaryl. Optional substituents for aryl or heteroaryl R⁶ are C₁₋₂₀ alkyl.

In one preferred arrangement, R⁸ is Ar⁶ and each of Ar⁴, Ar⁵ and Ar⁶ are independently and optionally substituted with one or more C₁₋₂₀ alkyl groups.

Particularly preferred units satisfying Formula (VI) include units of Formulae 1-4:

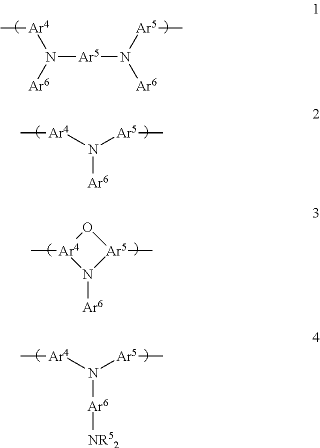

Where present, preferred substituents for Ar⁶ include substituents as described for Ar⁴ and Ar⁵, in particular alkyl and alkoxy groups.

Ar⁴, Ar⁵ and Ar⁶ are preferably phenyl, each of which may independently be unsubstituted or substituted with one or more substituents as described above.

In another preferred arrangement, Ar⁴, Ar⁵ and Ar⁶ are phenyl, each of which may be unsubstituted or substituted with one or more C₁₋₂₀ alkyl groups, and r=1.

In another preferred arrangement, Ar⁴ and Ar⁵ are phenyl, each of which may be unsubstituted or substituted with one or more C₁₋₂₀ alkyl groups, and R⁸ is 3,5-diphenylbenzene wherein each phenyl of R⁸ may be unsubstituted or substituted with one or more C₁₋₂₀ alkyl groups.

In another preferred arrangement, n, x and y are each 1 and Ar⁴ and Ar⁵ are phenyl linked by an oxygen atom to form a phenoxazine ring, and R⁸ is phenyl or 3,5-diphenylbenzene that is unsubstituted or substituted with one or more C₁₋₂₀ alkyl groups.

Triazines form an exemplary class of electron-transporting units, for example optionally substituted di- or tri-(hetero)aryltriazine attached as a side group through one of the (hetero)aryl groups. Other exemplary electron-transporting units are pyrimidines and pyridines; sulfoxides and phosphine oxides; benzophenones; and boranes, each of which may be unsubstituted or substituted with one or more substituents, for example one or more C₁₋₂₀ alkyl groups.

Exemplary electron-transporting units CT have formula (VII):

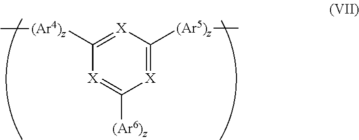

wherein Ar⁴, Ar⁵ and Ar⁶ are as described with reference to formula (VI) above, and may each independently be substituted with one or more substituents described with reference to Ar⁴, Ar⁵ and Ar⁶, and z in each occurrence is independently at least 1, optionally 1, 2 or 3 and X is N or CR⁷, wherein R⁷ is H or a substituent, preferably H or C₁₋₁₀ alkyl. Preferably, Ar⁴, Ar⁵ and Ar⁶ of formula (VII) are each phenyl, each phenyl being optionally and independently substituted with one or more C₁₋₂₀ alkyl groups.

In one preferred embodiment, all 3 groups X are N.

If all 3 groups X are CR⁷ then at least one of Ar¹, Ar² and Ar³ is preferably a heteroaromatic group comprising N.

Each of Ar⁴, Ar⁵ and Ar⁶ may independently be substituted with one or more substituents. In one arrangement, Ar⁴, Ar⁵ and Ar⁶ are phenyl in each occurrence. Exemplary substituents include R¹¹ as described above with reference to formula (VI), for example C₁₋₂₀ alkyl or alkoxy.

Ar⁶ of formula (VII) is preferably phenyl, and is optionally substituted with one or more C₁₋₂₀ alkyl groups or a crosslinkable unit. The crosslinkable unit may or may not be a unit of formula (I) bound directly to Ar⁶ or spaced apart from Ar⁶ by a spacer group.

A preferred repeat unit of formula (VII) is 2,4-6-triphenyl-1,3,5-triazine wherein the phenyl groups are unsubstituted or substituted with one or more C₁₋₂₀ alkyl groups.

The charge-transporting units CT may be provided as distinct repeat units formed by polymerising a corresponding monomer. Alternatively, the one or more CT units may form part of a larger repeat unit, for example a repeat unit of formula (VIII):

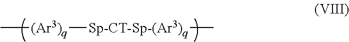

wherein CT represents a conjugated charge-transporting group; each Ar³ independently represents an unsubstituted or substituted aryl or heteroaryl; q is at least 1, optionally 1, 2 or 3; and each Sp independently represents a spacer group forming a break in conjugation between Ar³ and CT.

Sp is preferably a branched, linear or cyclic C₁₋₂₀ alkyl group.

Exemplary CT groups may be units of formula (VI) or (VII) described above.

Ar³ is preferably an unsubstituted or substituted aryl, optionally an unsubstituted or substituted phenyl or fluorene. Optional substituents for Ar³ may be selected from R³ as described above, and are preferably selected from one or more C₁₋₂₀ alkyl substituents.

q is preferably 1.

The polymer may comprise repeat units that block or reduce conjugation along the polymer chain and thereby increase the polymer bandgap. For example, the polymer may comprise units that are twisted out of the plane of the polymer backbone, reducing conjugation along the polymer backbone, or units that do not provide any conjugation path along the polymer backbone. Exemplary repeat units that reduce conjugation along the polymer backbone are substituted or unsubstituted 1,3-substituted phenylene repeat units, and 1,4-phenylene repeat substituted with a C₁₋₂₀ alkyl group in the 2- and/or 5-position, as described above with reference to formula (V).

The molar percentage of charge transporting repeat units in the polymer, for example repeat units of formula (VI), (VII) or (VIII), may be in the range of up to 75 mol %, optionally in the range of up to 50 mol % of the total number of repeat units of the polymer.

The compound of formula (I) may be provided in an amount of at least 0.5 mol % relative to the host material, optionally in the range of 1-25 mol %. In the case of a polymer, the molar % of the compound of formula (I) is the molar % relative to the total number of moles of repeat units of the polymer.

### Polymer Synthesis

Preferred methods for preparation of conjugated polymers, such as polymers comprising one or more of repeat units of formulae (IV), (V), (VI), (VII) and (VIII) as described above, comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable pi-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups. Likewise, an end group or side group may be bound to the polymer by reaction of a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular copolymers may be prepared when both reactive groups of a first monomer are boron and both reactive groups of a second monomer are halogen.

As alternatives to halides, other leaving groups capable of participating in metal insertion include sulfonic acids and sulfonic acid esters such as tosylate, mesylate and triflate.

### White OLEDs

An OLED containing a compound of formula (I) may emit white light.

The emitted white light may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

White light may be formed of blue emission from a compound of formula (I), and one or more fluorescent or phosphorescent materials emitting at longer wavelengths that, together with emission of the compound of formula (I), provide white light. White light may be provided by blue emission and longer wavelength excimer emission from a compound of the invention, in which case the compound of the invention may be the only light-emitting material of a white light emitting composition.

A white-emitting OLED may have a single light-emitting layer emitting white light, or may contain two or more light-emitting layers wherein the light emitted from the two or more layers combine to provide white light.

### Hole Injection Layers

A conductive hole injection layer, which may be formed from a conductive organic or inorganic material, may be provided between the anode and the light-emitting layer or layers of an OLED to improve hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

### Charge Transporting and Charge Blocking Layers

A hole transporting layer may be provided between the anode and the light-emitting layer or layers. Likewise, an electron transporting layer may be provided between the cathode and the light-emitting layer or layers.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A charge-transporting layer or charge-blocking layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group.

If present, a hole transporting layer located between the anode and the light-emitting layers preferably has a HOMO level of less than or equal to 5.5 eV, more preferably around 4.8-5.5 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 2.5-3.5 eV as measured by square wave cyclic voltammetry. For example, a layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may contain a hole-transporting (hetero)arylamine, such as a homopolymer or copolymer comprising hole transporting repeat units of formula (VI). Exemplary copolymers comprise repeat units of formula (VI) and optionally substituted (hetero)arylene co-repeat units, such as phenyl, fluorene or indenofluorene repeat units as described above, wherein each of said (hetero)arylene repeat units may optionally be substituted with one or more substituents such as alkyl or alkoxy groups. Specific co-repeat units include fluorene repeat units of formula (IV) and optionally substituted phenylene repeat units of formula (V) as described above.

If a charge-transporting layer is provided adjacent to a light-emitting layer containing a compound of formula (I) then the triplet energy level of the material or materials of the charge transporting layer are preferably at least the same as or higher than that of the compound of formula (I).

An electron transporting layer may contain a polymer comprising a chain of optionally substituted arylene repeat units, such as a chain of fluorene repeat units.

### Cathode

The cathode is selected from materials that have a workfunction allowing injection of electrons into the light-emitting layer. Other factors influence the selection of the cathode such as the possibility of adverse interactions between the cathode and the light-emitting material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Formulation Processing

A compound of formula (I) may be dispersed or dissolved in a solvent or mixture of two or more solvents to form a formulation that may be used to form a layer containing the compound by depositing the formulation and evaporating the solvent or solvents. The formulation may contain one or more further materials in addition to a compound of formula (I), for example the formulation may contain a host material. All of the components of the formulation may be dissolved in the solvent or solvent mixture, in which case the formulation is a solution, or one or more components may be dispersed in the solvent or solvent mixture. Suitable solvents for use alone or in a solvent mixture include aromatic compounds, preferably benzene, that may be unsubstituted or substituted. Preferably, substituents are selected from halogen (preferably chlorine), C1-10 alkyl and C1-10 alkoxy. Exemplary solvents are toluene, xylene, chlorobenze, and anisole.

Techniques for forming layers from a formulation include printing and coating techniques such spin-coating, dip-coating, roll printing, screen printing and inkjet printing.

Multiple organic layers of an OLED may be formed by deposition of formulations containing the active materials for each layer.

During OLED formation, a layer of the device may be crosslinked to prevent it from partially or completely dissolving in the solvent or solvents used to deposit an overlying layer. Layers that may be crosslinked include a hole-transporting layer prior to formation by solution processing of an overlying light-emitting layer, or crosslinking of one light-emitting layer prior to formation by solution processing of another, overlying light-emitting layer.

Suitable crosslinkable groups include groups comprising a reactive double bond such and a vinyl or acrylate group, or a benzocyclobutane group. Where a layer to be crosslinked contains a polymer, the crosslinkable groups may be provided as substituents of repeat units of the polymer.

Coating methods such as spin-coating are particularly suitable for devices wherein patterning of the light-emitting layer is unnecessary—for example for lighting applications or simple monochrome segmented displays.

Printing methods such as inkjet printing are particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

### EXAMPLES

### Emitter Examples

Emitter Example 1 was prepared according to the following reaction scheme:

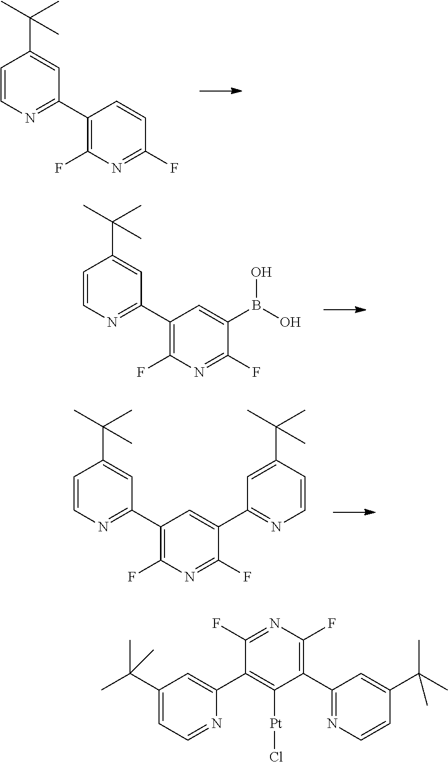

### Emitter Example 1

### 2,6-difluoro-3-(4-tert-butylpyridin-2-yl)pyridine

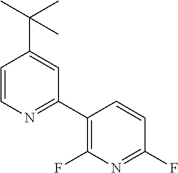 [SMILES: CC(C)(C)c1ccnc(-c2ccc(F)nc2F)c1]

A mixture of 2-chloro-4-terbutylpyridine (1.79 g, 10.5 mmol), 2,6-difluoro-3 pyridylboronic acid (2.6 g, 16.4 mmol), Pd(PPh₃)4 (400 mg, 0.35 mmol), 2M aqueous solution of potassium carbonate (25 ml, 50 mmol) and 1,4-dioxane (80 ml) was deaerated by bubbling nitrogen through the mixture for 15 minutes. The mixture was stirred at 70° C. (bath) for 15 hours. The mixture was evaporated to a volume of approximately 30 ml. The residue was extracted with hexane (2×30 mL). The organic layers were washed with brine (20 mL) and dried over MgSO₄. After the evaporation of the solvent the product was purified by column chromatography (silicagel, ethyl acetate/hexane 1/2) and dried in high vacuum at room temperature. Yield 2.3 g, 88%.

### 2,6-difluoro-5-(4-tert-butylpyridin-2-yl)-3-pyridineboronic acid

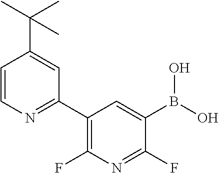 [SMILES: CC(C)(C)c1ccnc(-c2cc(B(O)O)c(F)nc2F)c1]

To a solution of 2,2,6,6-tetramethylpiperidine (1.68 g, 2 ml, 14.2 mmol, 1.53 eq, 141 g/mol, d=0.837 g/ml) in dry THF (35 mL) n-butyllithium (1.6M solution in hexanes (Aldrich), 7 ml, 11.2 mmol, 1.2 eq) was added dropwise. During addition, the temperature was maintained below −35° C. The solution was stirred for 20 min at −10° C.-0° C. The solution was cooled to −76° C., triisopropylborate (3.2 ml, 2.6 g, 13.9 mmol, 1.5 eq, d=0.815 g/mol) was added dropwise. The temperature was maintained below −70° C. during this addition. Starting difluoro derivative (2.3 g, 9.27 mmol) was dissolved in dry THF (15 mL) and added dropwise to the above mixture. During this addition, the temperature is maintained below −70° C. The solution was stirred at −76° C. for 60 min. The flask was taken from the cooling bath and the temperature rose till +20° C. At this point glacial acetic acid (8 ml) and water (8 ml) were added. After stirring at room temperature for 10 minutes, all volatiles were removed by rotary evaporation under reduced pressure. The residue was treated with water (150 ml). Formed solid was filtered off, washed with water (50 ml) and hexane (20 ml). Yield 2.35 g, 87%).

### 2,6-difluoro-3,5-di(4-tert-butylpyridin-2-yl)pyridine

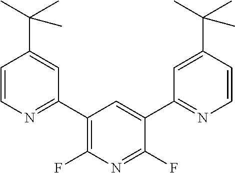 [SMILES: CC(C)(C)c1ccnc(-c2cc(-c3cc(C(C)(C)C)ccn3)c(F)nc2F)c1]

A mixture of 2,6-difluoro-5-(4-tert-butylpyridin-2-yl)-3-pyridineboronic acid (840 mg, 2.8 mmol), 2-bromo-4-tert-butylpyridine hydrobromide (1 g, 3.4 mmol), Pd(OAc)2 (44 mg), PPh3 (103 mg), dioxane (25 ml) was deaerated by bubbling nitrogen through the mixture for 15 min. 2M aqueous solution of K₂CO₃ (4 ml, 8 mmol) was added and the mixture was degassed for additional 10 minute. The mixture was then stirred at 60° C. for 12 hours. The mixture was evaporated to dryness, DCM (20 ml) and anhydrous MgSO₄ were added, and the mixture was filtered. The filtrate was evaporated to dryness. The product was isolated from the residue by the means of column chromatography (silicagel, ethyl acetate/petrol ether 1/5 vol. Rf=0.2). Yellowish oil. Yield 197 mg 18%. 1H NMR (270 MHz, CDCl3) δ=9.27 ppm (t, J=9.3 Hz, 1H), 8.63 (dd, J=5.3 Hz, J=0.7 Hz, 2H), 7.83 (m, 2H), 7.30 (dd, J=5.3 Hz, J=1.8 Hz, 2H), 1.38 (s, 18H)

### Emitter Example 1

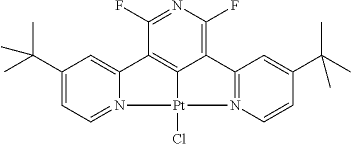

A mixture of the ligand (170 mg, 0.45 mmol), potassium tetrachloroplatinate (1.85 mg, 0.45 mmol) and acetic acid (50 ml) was degassed by bubbling nitrogen through the mixture and then heated under reflux. After 3 hours of reflux, AcOH was evaporated to dryness, DCM (20 ml) was added, and the mixture was filtered. The filtrate evaporated to dryness, then dissolved in DCM and chromatographed (silicagel, DCM/EA 10/1) to give pure product. Yield 50 mg (18%).

The substituents on the outer pyridine rings of Emitter Example 1 are both the same, however it will be appreciated that attachment of the two outer pyridine rings to the central pyridine ring in separate steps allows for synthesis of emitters with different (asymmetric) substitution of the outer pyridine rings, including emitters in which the two outer pyridine rings are substituted with different substituents; substituted in different positions; and where one outer pyridine is substituted with one or more substituents and the other outer pyridine ring is unsubstituted.

Calculated energy levels and triplet levels of Examples 1-3 and Comparative Emitter 1 are provided in Table 1. For the ground state geometry optimisation, the density functional theory (DFT) with the level of B3LYP is used (Gaussian 03 software). Based on these results, the HOMO and LUMO energy are calculated. Then, the time dependent density functional theory with the level of B3LYP is used for the calculation of triplet (T1) energy. For all DFT and TDDFT calculations, 6-31 g* is used as the basis, but when 6-31 g* is unavailable, LANL2DZ is used instead. (e.g., 6-31 g* for C, N and H, but LANL2DZ for Pt.)

Comparative Emitter 1 is disclosed in Appl. Phys. Lett. 93, 2008, 193305.

TABLE 1
Calculated energy levels and peak wavelength

| | | | Peak |
|---|---|---|---|
| | HOMO | LUMO | wavelength |
| Emitter | (eV) | (eV) | (nm) |
| Emitter Example 1 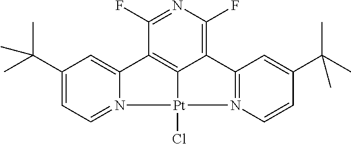 | −5.854 | −1.974 | 435 |
| Emitter Example 2 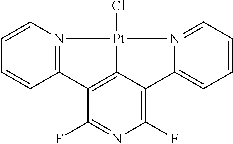 | −6.04 | −2.24 | 446 |
| Emitter Example 3 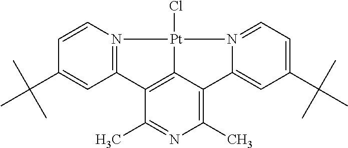 | −5.545 | −1.761 | 444 |
| Comparative Emitter 1 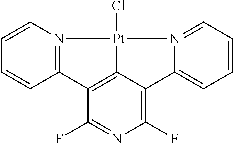 | −5.73 | −2.05 | 471 |

Emitter Examples 1-3 are all bluer (shorter peak wavelength) than Comparative Emitter 1.

The peak wavelength of Emitter Example 1 is blue-shifted relative to Comparative Emitter 1. Without wishing to be bound by any theory, it is believed that this blue shift is due to the central pyridine ring of Emitter Example 1 being electron deficient relative to the phenyl ring of Comparative Emitter 1.

The alkyl groups of Emitter Example 2 cause a blue shift relative to Emitter Example 1. Without wishing to be bound by any theory, it is believed that electron-donating groups on the outer rings of the tridentate ligand cause a blue shift. As can be seen from Emitter Example 3, in which the central ring of the tridentate ligand is substituted with methyl rather than fluorine, the electron-donating substituents on the outer rings provide a material having a shorter peak wavelength than Comparative Emitter 1 even if the central pyridine ring is not substituted with electron-withdrawing groups.

The substitutents on the central and outer rings may be selected so as to tune the colour of emission of the metal complex.

A shift to a longer peak wavelength may be achieved by substitution of the central ring with one or two electron-donating substituents and/or substitution of one or both of the outer rings with one or more electron-withdrawing substituents.

A shift to a shorter peak wavelength may be achieved by substitution of the central ring with one or two electron-withdrawing substituents and/or substitution of one or both of the outer rings with one or more electron-donating substituents.

### COMPOSITION EXAMPLES

A composition of Emitter Example 1 and poly(9-vinylcarbazole) (PVK) was dissolved in anisole, and the solution was deposited onto a glass substrate by spin-coating to form a film of the composition. Films having an emitter concentration of 1 wt % and 10 wt % relative to weight of PVK were prepared. For the purpose of comparison, the same compositions were prepared using Comparative Emitter 2, disclosed in J. Kalinowski et al., Adv. Mater. 2007, 19, 4000-4005, in place of Emitter Example 1:

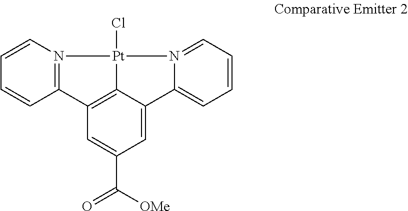

Photoluminescent quantum yield (PLQY) and CIE (x, y) co-ordinates were measured for these compositions.

For PLQY measurements films were spun from a suitable solvent (for example alkylbenzene, halobenzene, alkoxybenzene) on quartz disks to achieve transmittance values of 0.3-0.4. Measurements were performed under nitrogen in an integrating sphere connected to Hamamatsu C9920-02 with Mercury lamp E7536 and a monochromator for choice of exact wavelength.

TABLE 2
PLQY data

| Composition | | PLQY | CIE | CIE |
|---|---|---|---|---|
| Number | Composition | (%) | X | Y |
| 1 | PVK: Comparative Emitter 2 | 79 | 0.190 | 0.470 |
| | (99:1 wt %) | | | |
| 2 | PVK: Emitter Example 1 | 38 | 0.260 | 0.270 |
| | (99:1 wt %) | | | |
| 3 | PVK: Comparative Emitter 2 | 55 | 0.260 | 0.490 |
| | (90:10 wt %) | | | |
| 4 | PVK: Emitter Example 1 | 63 | 0.480 | 0.340 |
| | (90:10 wt %) | | | |

The efficiency at high (10%) concentration is higher for Emitter Example 1 than for Comparative Emitter 1. Without wishing to be bound by any theory, it is believed that the bulky substituents of Emitter Example 1 may prevent concentration quenching effects at high concentrations. The CIE y value is lower for Emitter Example 1 as compared to Comparative Emitter 1 at both 1 and 10 weight %.

FIG. 2 shows the photoluminescent spectra of the 10 weight % compositions 3 and 4 above. The peak emission of Example Emitter 1 (Composition 4) in the blue region is at a shorter wavelength than for Comparative Emitter 2 (Composition 3). Furthermore, blue-shifting has the effect of blue-shifting excimer emission, resulting in less excimer emission occurring in the infra-red region of the spectrum. In addition, an unexpectedly strong excimer emission of Emitters 1 and 2 is achieved in the red region of the spectrum compared to the emission of the Comparative Emitter 1 in this region.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A compound of formula (I): 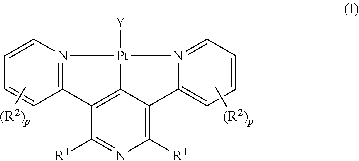
wherein R¹ in each occurrence is independently H or a substituent; R² in each occurrence is independently a substituent; p in each occurrence is 0, 1, 2, 3 or 4 and Y is a ligand, with the proviso that at least one R¹ is a substituent or at least one p is at least 1.

2. The compound according to claim 1 wherein both groups R¹ are a substituent and each p is independently 0, 1, 2, 3 or 4.

3. The compound according to claim 1 wherein at least one R¹ group is an electron-withdrawing group.

4. The compound according to claim 1 wherein each p is 0.

5. The compound according to claim 1 wherein at least one p is at least 1.

6. The compound according to claim 5 wherein each p is 1.

7. The compound according to claim 5 wherein the at least one R² group is an electron donating substituent.

8. The compound according to claim 5 wherein R² is selected from the group consisting of: hydrocarbyl; *—OR¹²; *—NR¹²; and *—BR¹²₂, wherein * represents a point of attachment to the metal complex and R¹² independently in each occurrence is a hydrocarbyl and wherein two R¹² groups linked to the same N or B atom may be linked to form a ring.

9. The compound according to claim 8 wherein the at least one R² comprises a tertiary carbon atom.

10. The compound according to claim 8 wherein the at least one R² is a C₁₋₂₀ alkyl.

11. (canceled)

12. The compound according to claim 1 wherein Y is selected from halogen, unsubstituted or substituted phenoxy, cyano and a group of formula: [symbol] wherein R¹² is a hydrocarbyl.

13. The compound according to claim 1 wherein a photoluminescence spectrum of the compound has a peak at a wavelength of less than 480 nm.

14. A composition comprising a charge-transporting host material and a compound according to claim 1.

15. The composition according to claim 14 wherein the compound of formula (I) is provided in an amount of at least 5 weight % of the composition.

16. A white light-emitting composition comprising a compound according to claim 1.

17. The white light emitting composition according to claim 16 wherein the composition comprises one or more light emitting materials in addition to the compound of claim 1.

18. The white light emitting composition according to claim 16, wherein the compound of claim 1 is the only light emitting material in the composition.

19. (canceled)

20. An organic light-emitting device comprising an anode, a cathode and a light-emitting layer between the anode and the cathode wherein the light-emitting layer comprises a compound according to claim 1.

21-23. (canceled)

24. The compound according to claim 3 wherein at least one R¹ group is fluorine.

25. The composition according to claim 14 wherein the compound of formula (I) is provided in an amount less than 10 weight % of the composition.
